(19) United States
(12) Patent Application Publication
(10) Pub. No.: US 2014/0003160 A1
(43) Pub. Date: Jan. 2, 2014

(54) High-Speed Sensing Scheme for Memory

(71) Applicants: Manish Trivedi, Ghaziabad (IN); Ankur Goel, Haryana (IN)

(72) Inventors: Manish Trivedi, Ghaziabad (IN); Ankur Goel, Haryana (IN)

(73) Assignee: LSI CORPORATION, Milpitas, CA (US)

(21) Appl. No.: 13/536,514

(22) Filed: Jun. 28, 2012

(51) Int. Cl. G11C 7/06; G11C 7/00; G11C 7/12; G11C 7/10

(52) U.S. Cl. 365/189.02; 365/189.05; 365/205; 365/203

(57) ABSTRACT

A sensing circuit for use in a memory including memory cells and at least one bitline coupled with the memory cells includes first and second sense amplifiers and a controller coupled with the sense amplifiers. The first sense amplifier is adapted to read a selected one of the memory cells coupled to the first sense amplifier via a corresponding bitline. The second sense amplifier is adapted to read a selected one of the memory cells coupled to the second sense amplifier via a corresponding bitline. The controller selectively connects one of the first and second sense amplifiers in an active path of the memory in a manner which enables one of the sense amplifiers to be operative in a precharge mode and another of the sense amplifiers to be concurrently operative in a sensing mode during a given memory cycle.

### BACKGROUND

In a data processing environment, computation throughput of a processor (e.g., central processing unit (CPU)) is determined primarily by instruction and/or data cache read access time and read cycle time. Consequently, the design of memory circuitry is critical to improving the overall speed performance of a data processing system. Increased usage of static random access memory (SRAM) in an integrated circuit (e.g., embedded SRAM) and statistical variations demand faster sensing schemes to meet modern processor computation requirements.

In a memory array, memory cells drive associated bitlines for reading the respective logical states of the cells. With the push for increased memory capacity, the number of memory cells connected with a given bitline in the memory has increased, thereby increasing bit-line parasitic capacitance. This increased bit-line capacitance, in turn, reduces the speed at which the respective voltage levels stored in the memory cells is developed on the bitlines and thus slows down voltage sensing. Sense amplifiers are used to amplify small differences in voltage developed on the bitlines when reading the logical states of corresponding memory cells. Thus, sense amplifiers, and memory sensing in general, play an important role in increasing the speed of memory since their performance strongly affects memory access time.

### SUMMARY

Embodiments of the invention, including but not limited to a sensing circuit, methods for reducing memory cycle access times and a memory circuit without regard to whether it is embedded in an integrated circuit or a standalone memory, provide a novel sensing scheme for reducing memory cycle time in a memory. To accomplish this, embodiments of the invention utilize a dual sense amplifier-based memory sensing scheme which essentially eliminates a dependence of memory cycle time on sense amplifier precharging.

In accordance with an embodiment of the invention, a sensing circuit for use in a memory including a plurality of memory cells and at least one bitline coupled with the memory cells includes first and second sense amplifiers and a controller coupled with the first and second sense amplifiers. The first sense amplifier is adapted to read a logical state of a selected one of the memory cells that is coupled to the first sense amplifier via a corresponding bitline. The second sense amplifier is adapted to read a logical state of a selected one of the memory cells that is coupled to the second sense amplifier via a corresponding bitline. The controller is operative to selectively connect one of the first and second sense amplifiers in an active path of the memory in a manner which enables one of the sense amplifiers to be operative in a precharge mode and another of the sense amplifiers to be concurrently operative in a sensing mode during a given memory cycle.

In accordance with another embodiment of the invention, a method is provided for reducing memory cycle time in a memory circuit including a plurality of memory cells, at least one bitline coupled with the memory cells, and at least two sense amplifiers. The method includes steps of: during a first memory cycle, enabling a first one of the sense amplifiers for reading a logical state of a selected one of the memory cells coupled to the first one of the sense amplifiers via a first corresponding bitline and enabling a second one of the sense amplifiers for precharging at least one sensing node in the second one of the sense amplifiers; and during a second memory cycle, enabling the second one of the sense amplifiers for reading a logical state of a selected one of the memory cells coupled to the second one of the sense amplifiers via a second corresponding bitline and enabling the first one of the sense amplifiers for precharging at least one sensing node in the first one of the sense amplifiers.

In accordance with a third embodiment of the invention, a memory circuit includes a plurality of bitlines, a plurality of memory cells and at least one sensing circuit. Each of the memory cells are adapted for connection with a corresponding one of the bitlines for selectively accessing the memory cell. The sensing circuit includes first and second sense amplifiers and a controller coupled with the first and second sense amplifiers. The first sense amplifier is adapted to read a logical state of a selected one of the memory cells that is coupled to the first sense amplifier via a corresponding bitline. The second sense amplifier is adapted to read a logical state of a selected one of the memory cells that is coupled to the second sense amplifier via a corresponding bitline. The controller is operative to selectively connect one of the first and second sense amplifiers in an active path of the memory in a manner which enables one of the sense amplifiers to be operative in a precharge mode and another of the sense amplifiers to be concurrently operative in a sensing mode during a given memory cycle.

Embodiments of the invention will become apparent from the following detailed description, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a schematic diagram depicting at least a portion of an exemplary memory circuit which can be modified to implement embodiments of the invention;

FIG. 2 is a schematic diagram depicting at least a portion of an exemplary sense amplifier circuit which is suitable for use in the memory circuit shown in FIG. 1;

FIG. 3 depicts illustrative timing waveforms for certain signals associated with the exemplary sense amplifier circuit shown in FIG. 2;

FIG. 4 is a schematic diagram conceptually depicting at least a portion of a sensing architecture employing a two-bit multiplexing (MUX2) configuration;

FIG. 5 is a schematic diagram conceptually depicting at least a portion of a sensing architecture employing a four-bit multiplexing (MUX4) configuration formed using a combination of multiple MUX2 configurations of the type shown in FIG. 4;

FIG. 6 is a schematic diagram depicting at least a portion of an exemplary memory sensing architecture providing reduced memory cycle time, according to an embodiment of the invention;

FIG. 7 depicts illustrative timing waveforms for certain signals associated with the exemplary memory sensing architecture shown in FIG. 6, according to an embodiment of the invention;

FIG. 8 conceptually illustrates simulation results showing a percentage improvement in cycle time for an exemplary memory sensing architecture in accordance with an embodiment of the invention compared with a conventional design; and

FIG. 9 is a schematic diagram depicting at least a portion of an exemplary sense amplifier circuit suitable for use in the illustrative memory sensing architecture shown in FIG. 6, according to another embodiment of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Embodiments of the invention will be described herein in the context of illustrative sense amplifier circuits and memory sensing methodologies for use in a memory. It should be understood, however, that embodiments of the invention are not necessarily limited to these or any other particular circuit arrangements. Rather, embodiments of the invention are directed more broadly to techniques for improving memory cycle time in a memory. Embodiments of the invention have wide use, for example, in data processing and storage applications, although embodiments of the invention are not limited to such applications. Moreover, it will become apparent to those skilled in the art given the teachings herein that numerous modifications can be made to the embodiments shown that are within the scope of the claimed invention. That is, no limitations with respect to the embodiments shown and described herein are intended or should be inferred.

Although embodiments of the invention will be described herein in the context of static random access memory (SRAM), it is to be understood that techniques according to embodiments of the invention are similarly applicable to other memory types, including, for example, dynamic random access memory (DRAM), static random access memory (SRAM), content-addressable memory (CAM), read-only memory (ROM), etc., either embedded or not (e.g., discrete memory). Moreover, for the purpose of describing and claiming embodiments of the invention, the term MISFET as used herein is intended to be construed broadly to encompass any type of metal-insulator-semiconductor field-effect transistor. The term MISFET is, for example, intended to encompass semiconductor field-effect transistors that utilize an oxide material as their gate dielectric (i.e., MOSFETs), as well as those that do not. In addition, despite a reference to the term “metal” in the acronym MISFET, the term MISFET is also intended to encompass semiconductor field-effect transistors wherein the gate is formed from a non-metal such as, for instance, polysilicon.

Although implementations of the present invention described herein may be implemented using p-channel MISFETs (hereinafter called “PMOS” (p-channel metal-oxide-semiconductor) or “PFET” (p-channel field-effect transistor) devices) and n-channel MISFETs (hereinafter called “NMOS” (n-channel metal-oxide-semiconductor) or NFET (n-channel field-effect transistor) devices), as may be formed using a complementary metal-oxide-semiconductor (CMOS) fabrication process, it is to be appreciated that the invention is not limited to such transistor devices and/or such a fabrication process, and that other suitable devices, such as, for example, FinFETs, bipolar junction transistors (BJTs), etc., and/or fabrication processes (e.g., bipolar, BiCMOS, etc.), may be similarly employed, with or without modification to the circuits described herein, as will be understood by those skilled in the art. Moreover, although preferred embodiments of the invention are typically fabricated in a silicon wafer, embodiments of the invention can alternatively be fabricated in wafers comprising other materials, including but not limited to Gallium Arsenide (GaAs), Indium Phosphide (InP), etc.

As previously stated, the design of sense amplifiers, and of the overall memory sensing architecture in general, plays a vital role in increasing the speed of a memory since sense amplifier performance strongly affects memory cycle time, particularly memory access time. The maximum timing interval required to complete a read/write operation to a memory is termed cycle time (i.e., the time between the start of one memory access and the time when the next memory access can begin). Read cycle time has two primary components: a read access interval, followed by a read precharge interval.

During a read access interval, the logic state of a given memory cell is sensed by a corresponding sense amplifier coupled with an associated bitline. During a read precharge interval, associated bitlines and sense amplifier nodes are precharged to a prescribed voltage level or levels in preparation for the next memory cycle. Typically, in sensing the status of the memory cell, the sense amplifier is turned on during the read access interval and remains on until the sensed data is latched; only after the data is latched is the read precharge operation initiated. A precharge operation thus becomes the last event to complete, making read cycle time considerably longer than write cycle time. This undesirably limits the maximum operating frequency of the memory.

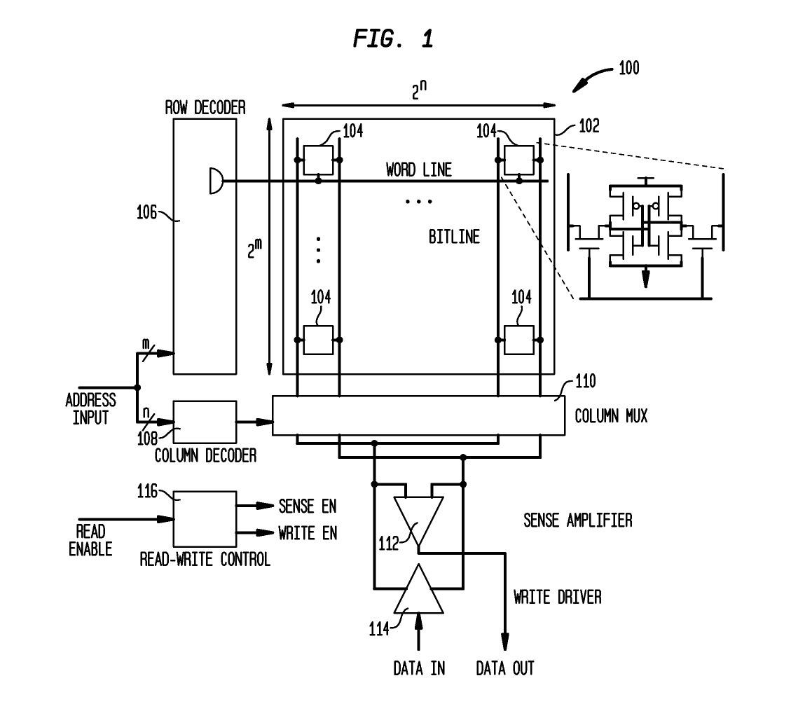

FIG. 1 is a schematic diagram depicting at least a portion of an exemplary memory circuit 100 which can be modified to implement aspects of the invention. The memory circuit 100 includes an array 102 of 2^{m} rows by 2ⁿ columns of memory cells 104, where m and n are integers. Each of the memory cells 104 in the array 102, in this embodiment, is implemented as a six-transistor (6T) SRAM cell comprising a pair of cross-coupled inverters as the storage element, as shown. It is to be appreciated that embodiments of the invention are not limited to a 6T SRAM memory cell, nor are embodiments of the invention limited to an SRAM architecture. Each of the 2^{m} rows of memory cells 104 includes a corresponding word line associated therewith, and each of the 2ⁿ columns of memory cells 104 includes a corresponding pair of bitlines (true and complement bitlines) associated therewith. Thus, each memory cell 104 is coupled to a unique combination of a word line and pair of bitlines. Depending upon the organization of the memory cells 104, more than one memory cell can be coupled to a given word line; likewise, more than memory cell can be coupled to a given bitline pair.

The memory circuit 100 further includes a row decoder 106 and a column decoder 108 adapted to access the memory cells 104. The row decoder 106, which forms at least a portion of row circuitry in the memory circuit 100, is connected with the word lines and is operative to receive at least a portion (m bits) of an address supplied to the memory circuit 100 and to select a given one of the 2^{m} word lines as a function of the address. The column decoder 108 is connected with a column multiplexer (MUX) 110, which together form at least a portion of column circuitry in the memory circuit 100. The column decoder 108 is operative to receive at least a portion (n bits) of the address supplied to the memory circuit 100 and to generate one or more control signals supplied to the column multiplexer 110 as a function of the address. The column multiplexer 110 is connected with the bitlines and is operative to access (i.e., read or write) a given one of the 2ⁿ bitline pairs as a function of the control signals generated by the column decoder 108. Thus, the column decoder 108 in conjunction with the column multiplexer 110 are operative to connect one of the 2ⁿ bitline columns to peripheral circuitry. In this manner, the m+n-bit address identifies the memory cell 104 which is to be accessed.

The peripheral circuitry to be connected with the bitlines comprises a sense amplifier 112 and a write driver 114. The sense amplifier 112 is connected with an output of the column multiplexer 110 and is operative to read a logical state of a selected memory cell during a read operation (and during a refresh operation in a DRAM context). The write driver 114 is connected with the output of the column multiplexer 110 (i.e., in parallel with the sense amplifier 112) and is operative to write a prescribed logical state to a selected memory cell during a write operation. The sense amplifier 112 and the write driver 114 are not operative concurrently. Although only one sense amplifier 112 and one write driver 114 are shown, it is to be understood that there may be more than one sense amplifier and/or write driver in the memory circuit 100. For example, in some embodiments, a separate sense amplifier may be used for each bit column, thereby eliminating the need for a column multiplexer. Control signals for activating the sense amplifier 112 during a read operation or for activating the write driver 114 during a write operation are generated by a read-write control block 116 as a function of a read enable signal supplied thereto.

Prior to a read operation, the bitlines are precharged to a prescribed voltage level, such as, for example, at or near a positive voltage supply (e.g., VDD). During a read operation, when a selected word line is asserted (e.g., active high), an access transistor (e.g., NFET device) connected with a memory cell storing a logic low value (i.e., “0”) turns on and starts discharging a corresponding bitline, while a corresponding complementary bitline remains at its precharged state, thus resulting in a differential voltage being developed across the bitline pair. Since the current generated by a memory cell is generally small and a capacitance of the bitlines is generally high, the bitline discharge rate will be slow. Moreover, the differential voltage developed across the bitline pair will be small. The sense amplifier 112 is designed to speed up the RAM access by amplifying the small differential bitline signal and eventually driving a data output signal (data out) indicative of the differential bitline signal to external circuitry.

During a write operation, write data (data in) is transferred to a desired bitline column(s) by driving the data onto the selected bitline pair(s), for example by grounding either the bitline or its complement. If the selected memory cell data is different from the write data, then the logic high (i.e., “1”) node is discharged when the corresponding access transistor connects such node to the discharged bitline, thereby causing the memory cell to be written with the bitline data value.

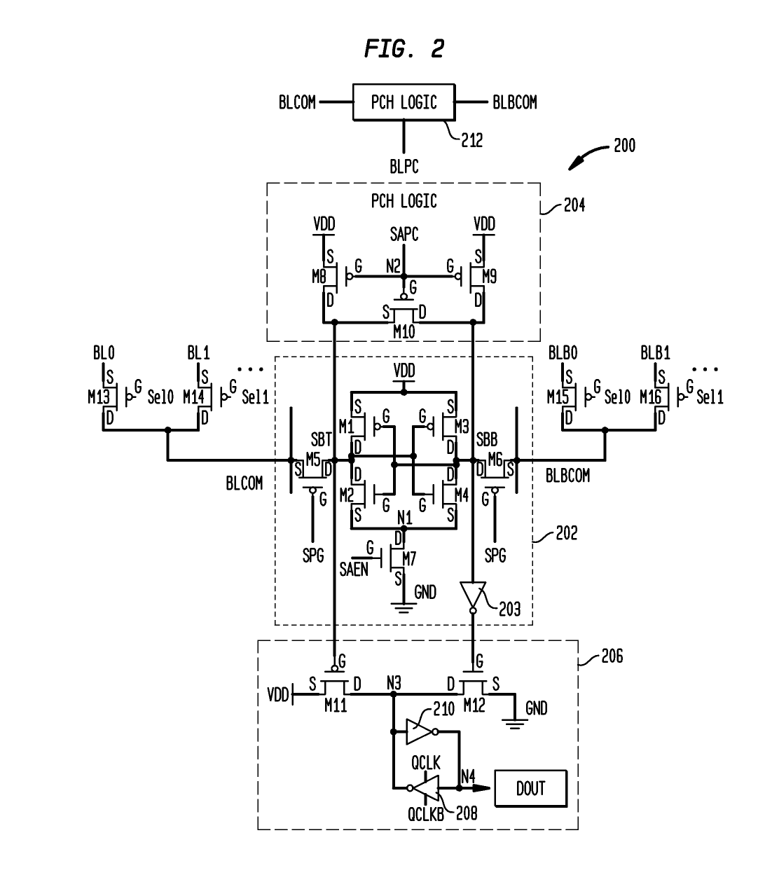

With reference now to FIG. 2, a schematic diagram depicts at least a portion of an exemplary sense amplifier 200 suitable for use in the memory circuit 100 shown in FIG. 1. The sense amplifier 200 comprises three primary functional blocks: a sensing circuit 202, sense amplifier precharge (PCH) logic 204 and a latch circuit 206. The sensing circuit 202 includes a first PFET, M1, a first NFET, M2, a second PFET, M3, a second NFET, M4, a third PFET, M5, and a fourth PFET, M6. A source (S) of PFET M1 is adapted for connection with a first voltage supply, VDD, a drain (D) of M1 is connected with a drain of NFET M2 at node SBT, a gate (G) of M1 is connected with a gate of M2 at node SBB, and a source of M2 is connected with a source of NFET M4 and a drain of NFET M7 at node N1. A drain of NFET M4 is connected with a drain of PFET M3 at node SBB, a source of M3 is adapted for connection with VDD, and gates of M3 and M4 are connected together at node SBT. A source of NFET M7 is adapted for connection with a second voltage supply, GND, and a gate of M7 is adapted to receive a first control signal, SAEN, which in this embodiment is a sense amplifier enable signal. PFETs M5 and M6 function essentially as switches which connect nodes SBT and SBB to corresponding common bitlines, BLCOM and BLBCOM, respectively. Nodes SBT and SBB form “true” “complement” outputs, respectively, of the sensing circuit 202.

The common bitlines BLCOM and BLBCOM, which are complements of one another, represent outputs of the column multiplexer (110 in FIG. 1) which includes a plurality of transistors operative to connect a selected one of the bitlines to a corresponding one of the common bitlines. More particularly, the column multiplexer (110 in FIG. 1) includes a first PFET M13 operative to connect bitline BL0 to common bitline BLCOM as a function of a corresponding control signal (SEL0), a second PFET M14 operative to connect bitline BL1 to common bitline BLCOM as a function of a corresponding control signal (SEL1), a third PFET M15 operative to connect bitline BLB0 to common bitline BLBCOM as a function of the control signal SEL0, and a fourth PFET M16 operative to connect bitline BLB1 to common bitline BLBCOM as a function of the control signal SEL1.

The sense amplifier precharge logic 204 is coupled with the sensing circuit 202 and is operative to selectively connect certain nodes in the sense amplifier 200 to a prescribed voltage source, which is VDD in this illustrative embodiment, as a function of a control signal, SAPC, supplied to the sense amplifier precharge logic. The sense amplifier precharge logic 204 comprises a first PFET, M8, a second PFET, M9, and a third PFET, M10. Sources of PFETs M8 and M9 are adapted for connection with the prescribed voltage source VDD, a drain of M8 and a source of PFET M10 are connected with node SBT, drains of M9 and M10 are connected with node SBB, and gates of M8, M9 and M10 are adapted to receive the control signal SAPC. Thus, when the control signal SAPC is at a low level, M8, M9 and M10 are turned on thereby connecting nodes SBT and SBB to VDD, and when SAPC is at a high level, M8, M9 and M10 are turned off thereby effectively disabling the sense amplifier precharge logic 204 and allowing nodes SBT and SBB to be defined by the differential voltage developed on common bitlines BLCOM and BLBCOM from a selected memory cell. It is to be appreciated that other circuit arrangements for selectively precharging one or more nodes in the sense amplifier 200 to a prescribed voltage are similarly contemplated by embodiments of the invention.

The latch circuit 206 is coupled with the sensing circuit 202 and is operative to selectively store a logical state of the memory cell sensed by the sensing circuit. The latch circuit 206, in this embodiment, comprises a PFET, M11 and an NFET, M12, and a pair of cross-coupled inverters. Specifically, a source of PFET M11 is adapted for connection with VDD, a drain of M11 is connected with a drain of NFET M12 at node N3, a source of M12 is adapted for connection with ground, a gate of M11 is connected with node SBT and is adapted to receive the true output of the sensing circuit 202, and a gate of M12 is connected with node SBB through an inverter 203 and is adapted to receive an inverse of the complement output of the sensing circuit. An output of a first inverter 208, which is a clocked inverter, and an input of a second inverter 210, which may be a standard inverter, are connected to node N3, and an input of inverter 208 is connected with an output of inverter 210 at node N4 for generating an output signal, DOUT, of the sense amplifier 200.

The inverter 208 is adapted to receive clock signals QCLK and QCLKB, which are complements of one another and function as latch control signals. When the signals QCLK and QCLKB are not asserted, the inverter 208 is placed in a high-impedance state. Latch control signals QCLK and QCLKB are generated in a manner that places the inverter 208 in a high-impedance state during read access internally to update a status on DOUT as per sensed data; otherwise, inverter 208 provides positive feedback to inverter 210 to latch sensed data until it is written in a subsequent cycle.

In terms of operation, since output signals SBT and SBB are, themselves, complements of one another, the signals received at the gates of M11 and M12 will essentially be the same, thereby ensuring that M11 and M12 are not turned on concurrently, thus preventing a short-circuit path between VDD and ground. During a precharge mode, when nodes SBT and SBB are both pulled up to VDD through activation of the sense amplifier precharge circuit 204, M11 and M12 will both be turned off, with the output signal DOUT being latched through inverters 208 and 210.

During a bitline precharge phase, bitline precharge logic 212, which does not necessarily reside in the sense amplifier 200, is operative to set the common bitlines BLCOM and BLBCOM to a prescribed voltage level, preferably VDD, via a control signal, BLPC, supplied to the bitline precharge logic. The bitline precharge logic 212 may be implemented using circuitry similar to the sense amplifier precharge logic 204 previously described, or using an alternative circuit arrangement. Prior to one of the word lines in the memory circuit (e.g., memory circuit 100 in FIG. 1) being asserted, such as by setting a selected word line to a high level indicative of the start of a read access, the bitline precharge logic 212 and the sense amplifier precharge logic 204 are both disabled, such as, for example, by setting the precharge control signals BLPC and SAPC to a high level. During the read access, the selected word line is set to a high level while the other word lines remain at a low level (i.e., deselected). With the precharge circuitry 204 and 212 disabled, the selected memory cell discharges the coupled bitline BL or BLB to allow a differential voltage to develop across the bitlines.

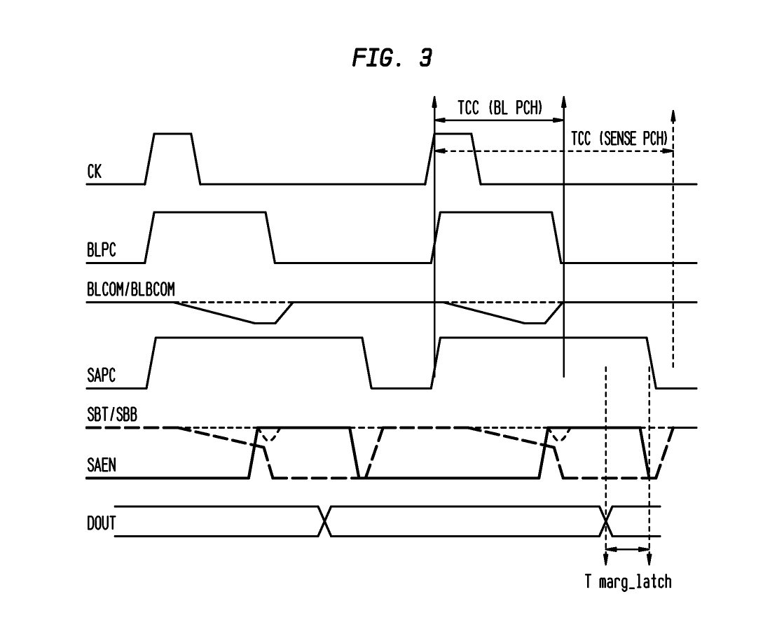

Control circuitry in the memory circuit (not explicitly shown) is operative to track the discharge time of the bitline such that a sufficient differential voltage is developed across a selected bitline pair BL/BLB for sensing by the sense amplifier 200. With reference additionally to FIG. 3, which depicts illustrative timing waveforms for certain signals (CK, BLPC, BLCOM/BLBCOM, SAPC, SBT/SBB, SAEN and DOUT) associated with the exemplary sense amplifier circuit 200 shown in FIG. 2, once a sufficient differential voltage is developed across a selected bitlines BL/BLB (represented in FIG. 3 as BLCOM/BLBCOM), the sense amplifier enable signal SAEN is asserted high to enable sensing of the bitlines by the sensing circuit 202. When SAEN is asserted high, the bitlines are isolated from the sense amplifier, for example by setting control signal SPG high to thereby turn off PFETs M5 and M6, and the bitline precharge operation can be started. Although not explicitly shown in FIG. 3, the signal SPG may be the same as the signal SAPC used to enable the sense amplifier pre-charge logic 204. The enable signal SAEN should remain asserted high until the output data DOUT is latched by the latch circuit 206, and only after DOUT has been latched is the sense amplifier internal node precharging operation started in preparation for the next read access cycle. To ensure integrity of the output data DOUT, a margin, Tmarg_latch, between the SAEN signal going low and the output data being latched is maintained.

An overall cycle time, TCC, associated with the memory circuit is determined primarily as a greater of the bitline precharge time, TCC (BL PCH), and the sense amplifier precharge time, TCC (Sense PCH). As apparent from FIG. 3, for the exemplary sense amplifier 200 depicted in FIG. 2, the sense amplifier precharge time TCC (Sense PCH) is larger than the bitline precharge time TCC (BL PCH) by approximately a width of the SAEN pulse. Consequently, sense amplifier precharge time, in the illustrative embodiment shown in FIG. 2, is a primary limitation on the overall memory cycle time.

Various other types of sense amplifiers have been proposed to enhance sensing speed, but in all known schemes, the sense amplifier precharge operation always starts after the bitline precharge operation, thus making the sense amplifier precharge operation inherently longer than the bitline precharge operation. Many conventional enhancements to the sense amplifier have targeted sense amplifier reaction improvement or sense amplifier offset reduction. However, as explained above, sense amplifier precharge time predominantly determines the cycle time, and none of these known approaches have provided a mechanism for reducing the influence of sense amplifier precharge time on the overall memory cycle time.

In accordance with embodiments of the invention, a dual sense amplifier-based sensing architecture is provided for every bit access to improve memory cycle time in a memory circuit (e.g., embedded memory). The sensing architecture according to embodiments of the invention beneficially eliminates the limitation on maximum operating frequency due to sense amplifier internal node precharging. To accomplish this, embodiments of the invention advantageously ensure that the bitline precharge operation, which is significantly less than the sense amplifier precharge operation, is the predominant factor in determining the overall memory cycle time. In exemplary embodiments utilizing aspects of the invention, an improvement in the read cycle time of about 15 to 30 percent are achieved based on the word width and word depth across the memory configuration range; thus, the percentage gain in performance will vary depending upon word size and bit size.

Another important benefit of embodiments of the invention includes the ability to more easily control (e.g., “tune”) a pulse width of the sense amplifier enable signal across multiple memory configurations due at least in part to localized control of sense amplifier data latch race conditions. In simpler terms, embodiments of the invention enable the SAEN pulse width to be extended to satisfy Tmarg_latch (i.e., sense amplifier data latch race conditions) across multiple memory configurations without penalizing cycle time which otherwise would have resulted due to delayed sense amplifier precharging caused by an increased SAEN pulse width.

Embodiments of the invention provide a novel sensing architecture which is operative to essentially de-isolate the sense amplifier from a read recovery path in the memory circuit when the sense enable control signal is asserted (e.g., high) and introduces a second sense amplifier in an active path of the memory circuit, making memory cycle time independent of sense reaction/data latch and sense precharging time. A finite state machine or alternative controller is operative to control swapping of the two sense amplifiers in the memory active path. Although described in further detail below in the context of SRAM, it is to be understood that aspects according to embodiments of the invention are also applicable to other memory types, as previously stated, with or without modification, as will become apparent to those skilled in the art given the teachings herein.

In SRAM array design, column multiplexing is often used to reduce the number of memory cells coupled to a given bitline by reducing the number of row in the array. Reduced bitline capacitance helps to improve slew rate and, in turn, sensing speed. In a complier, multiple column multiplexing options are provided, each option providing a trade-off between read access time, memory cycle time, and aspect ratio (which affects layout area). For example, a higher order column multiplexer helps to improve memory access time, but penalizes memory cycle time because of increased capacitive (i.e., horizontal) load on global signal lines. Higher order multiplexers are often preferred for their increased access speed and reduced soft error impact.

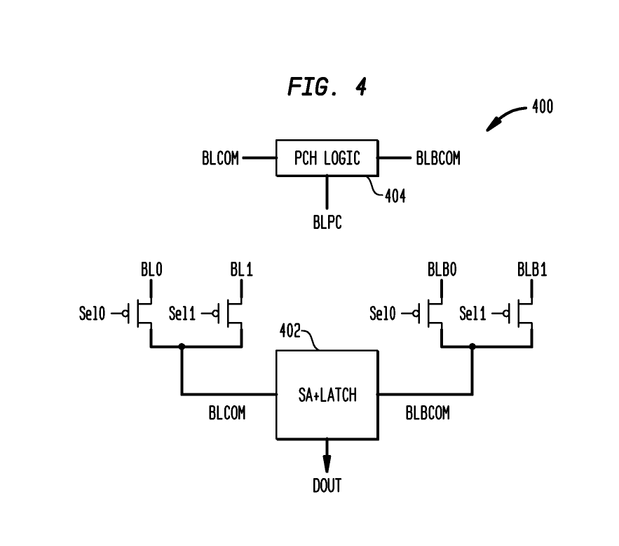

FIG. 4 is a schematic diagram conceptually depicting at least a portion of a sensing architecture 400 employing a MUX2 configuration. In a MUX2 configuration, two bitline columns (column 0, which includes bitline pairs BL0 and BLB0, and column 1, which include bitline pairs BL1 and BLB1) are multiplexed and coupled with a single sense amplifier 402. The sensing architecture also includes bitline precharge logic 404. In this manner, the sensing architecture 400 employing a MUX2 configuration is consistent with the illustrative sense amplifier architecture 200 shown in FIG. 2. Higher order multiplexing schemes can be formed using a combination of lower order multiplexing architectures.

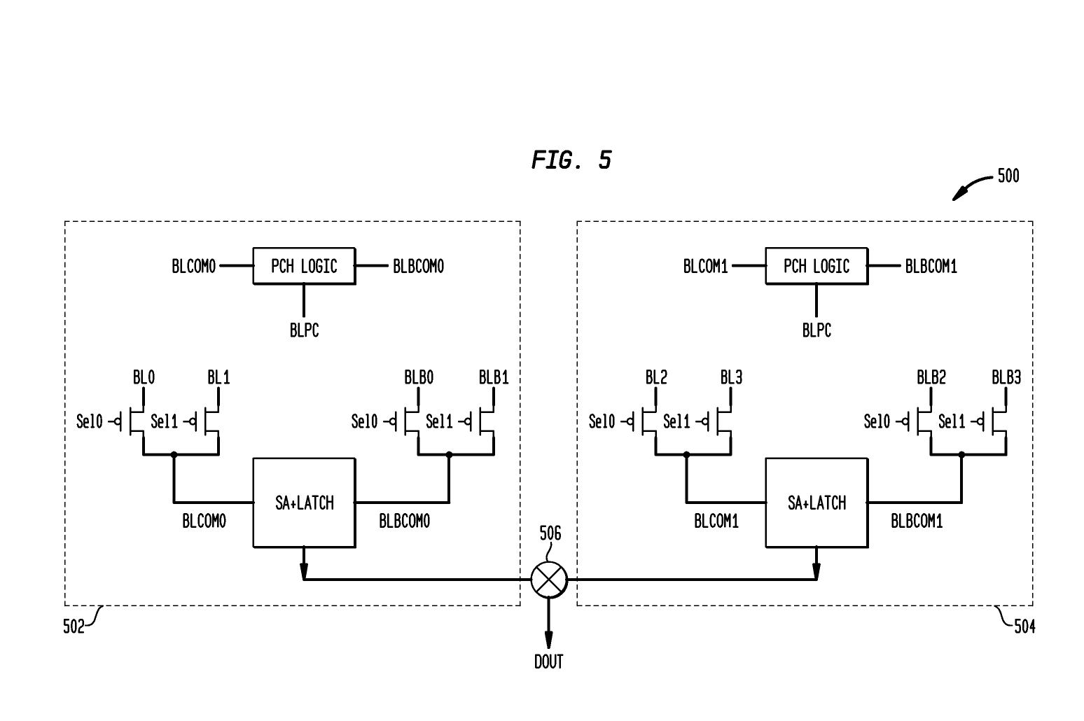

Consider, by way of illustration only, an exemplary MUX4 configuration, wherein four bitline columns, BL0, BL1, BL2 and BL3, are coupled to a single output data path, Dout. With reference now to FIG. 5, a schematic diagram conceptually depicts at least a portion of an exemplary memory sensing architecture 500 which employs a MUX4 configuration formed using two MUX2 configurations of the type shown in FIG. 4. More particularly, the memory sensing architecture 500 includes a first MUX2 sensing architecture 502 and a second MUX2 sensing architecture 504 each coupled to a multiplexer 506 generating a single data output, Dout.

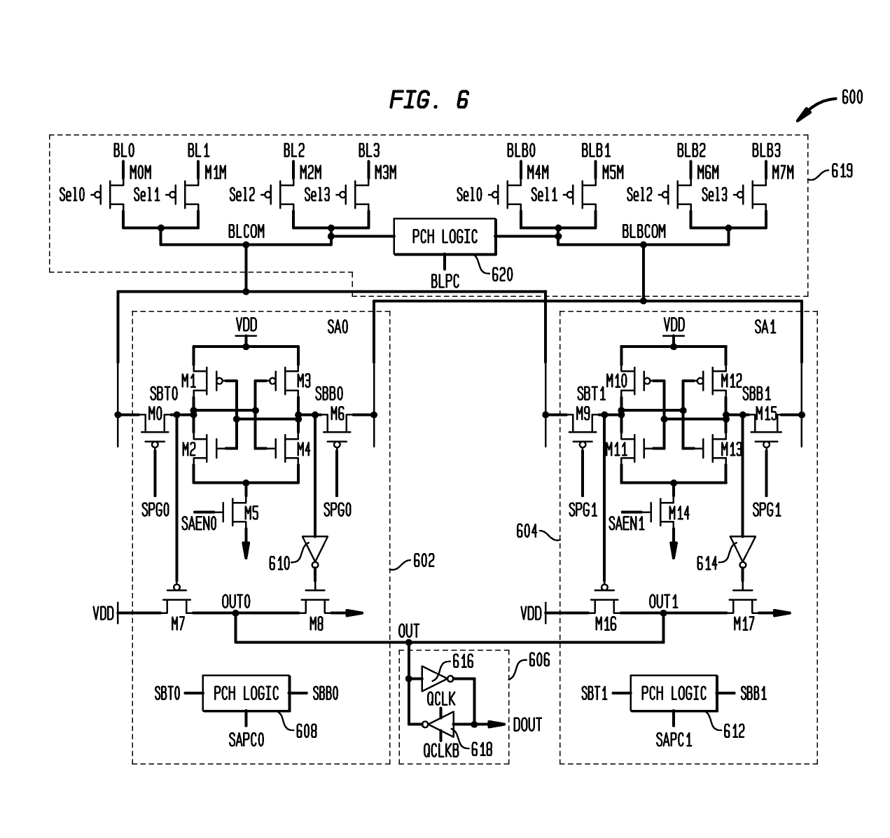

By way of illustration only and without limitation, FIG. 6 is a schematic diagram depicting at least a portion of an exemplary memory sensing architecture 600, according to an embodiment of the invention. The sensing architecture 600, in this embodiment, is implemented using a MUX4 configuration including a first sense amplifier (SA0) 602 and a second sense amplifier (SA1) 604 multiplexed together into a common latch circuit 606 to generate a single data output, DOUT. It is to be appreciated, however, that other connection arrangements (e.g., MUX2, etc.) are similarly contemplated. Moreover, embodiments of the invention are not limited to the specific sense amplifier arrangements shown. As will be described in further detail below, embodiments of the invention advantageously utilize multiple sense amplifiers per bit sensed in manner configured to reduce read cycle time and thereby increase memory sensing speed.

Each of the sense amplifiers 602 and 604, in this embodiment, comprises a sensing circuit including a pair of cross-coupled inverters coupled with a pair of differential bitlines via corresponding access devices. More particularly, the first sense amplifier 602 includes a first PFET M1, a first NFET M2, a second PFET M3, a second NFET M4 and a third NFET M5. A first source/drain of M1 and a first source/drain of M3 are adapted for connection with a first voltage source, which is VDD in this embodiment, a second source/drain of M1 is connected with a first source/drain of M2 at node SBT0, a second source/drain of M3 is connected with a first source/drain of M4 at node SBB0, a second source/drain of M2 and a second source/drain of M4 are connected with a first source/drain of M5, and a second source/drain of M5 is adapted for connection with a second voltage source, which is ground in this embodiment. Gates of M1 and M2 are connected with node SBB0, gates of M3 and M4 are connected with node SBT0, and a gate of M5 is adapted to receive a first control signal, SAEN0, which is a sense amplifier enable signal in this embodiment.

Node SBT0 is selectively connected to a first one of the differential bitlines, BLCOM, which is a true bitline in this embodiment, via a third PFET M0, or an alternative switching element, as a function of a second control signal, SPG0. Node SBB0 is selectively connected to a second one of the differential bitlines, BLBCOM, which is a complementary bitline in this embodiment, via a fourth PFET M6, or an alternative switching element, as a function of the second control signal SPG0. Thus, PFETs M0 and M6 serve as pass gates to selectively isolate internal nodes of the sense amplifier 602 from the common bitlines BLCOM and BLBCOM, respectively, as a function of control signal SPG0.

It is to be appreciated that, because a field-effect transistor (FET) device is symmetrical in nature, and thus bi-directional, the assignment of source and drain designations in the FET device is essentially arbitrary. Therefore, the source and drain of a given FET device (e.g., PFET or NFET) may be referred to herein generally as first and second source/drain, respectively, where “source/drain” in this context denotes a source or a drain.

The first sense amplifier 602 includes first precharge logic 608 which is coupled with nodes SBT0 and SBB0. The precharge logic 608 is operative to selectively precharge nodes SBT0 and SBB0 to a prescribed voltage level as a function of a sense amplifier precharge control signal, SPCN0, supplied thereto during a precharge mode of operation of the sense amplifier 602. Sense amplifier 602 further includes an output stage which, in this embodiment, comprises a PFET M7 and an NFET M8 connected in series between VDD and ground. Specifically, a first source/drain of M7 is adapted for connection with VDD, a second source/drain of M7 is connected with a first source/drain of M8 at node OUT0 which forms an output of the first sense amplifier 602, a second source/drain of M8 is adapted for connection with ground, a gate of M7 is connected with node SBT0, and a gate of M8 is connected with node SBB0 through an inverter 610. Here, an NFET is preferred for M8 in order to pass a strong “0” logic level to node OUT0, and thus inverter 610 is used for inverting signal SBB0 to activate the NFET pass gate M8. Alternative output stage arrangements are similarly contemplated.

Similarly, the second sense amplifier 604 includes a first PFET M10, a first NFET M11, a second PFET M12, a second NFET M13 and a third NFET M14. A first source/drain of M10 and a first source/drain of M12 are adapted for connection with VDD, a second source/drain of M10 is connected with a first source/drain of M11 at node SBT1, a second source/drain of M12 is connected with a first source/drain of M13 at node SBB1, a second source/drain of M11 and a second source/drain of M13 are connected with a first source/drain of M14, and a second source/drain of M14 is adapted for connection with ground. Gates of M10 and M11 are connected with node SBB1, gates of M12 and M13 are connected with node SBT1, and a gate of M14 is adapted to receive a third control signal, SAEN1, which is a sense amplifier enable signal in this embodiment.

Node SBT1 is selectively connected to a first one of the corresponding differential bitlines, BLCOM, which is a true bitline in this embodiment, via a third PFET M9 as a function of a fourth control signal, SPG1. Node SBB1 is selectively connected to a second one of the corresponding differential bitlines, BLBCOM, which is a complementary bitline in this embodiment, via a fourth PFET M15 as a function of the fourth control signal SPG1. Thus, PFETs M9 and M15 serve to isolate internal nodes of the sense amplifier 604 from the common bitlines BLCOM and BLBCOM, respectively, as a function of the control signal SPG1. The memory sensing architecture 600 is configured such that the control signals SPG0 and SPG1 are not asserted (e.g., low level) concurrently.

Advantageously, in this exemplary configuration, while one of the sense amplifiers is operative in a sensing mode the other sense amplifier is operative in a precharge mode to thereby beneficially speed the overall sensing operation. The particular sense amplifier modes of operation can be swapped for consecutive read cycles or during portions of a given read cycle. For example, during a first read cycle, the first sense amplifier 602 can be operative to sense a logical state of a selected memory cell while the second sense amplifier 604 is operative in a precharge mode in preparation for a subsequent read cycle. During a next consecutive ready cycle, the operational modes of the first and second sense amplifiers are swapped, such that the second sense amplifier is operative to sense the logical state of a selected memory cell and the first sense amplifier is operative in a precharge mode in preparation for the next ready cycle. During a next read cycle, the modes of operation of the two sense amplifiers are again swapped.

Furthermore, the sense amplifier enable signals SAEN0 and SAEN1, in this illustrative embodiment, are made different from the control signals SPG0 and SPG1 so that coupling between the common bitline pair BLCOM/BLBCOM, the sense amplifier sensing nodes SBT0/SBB0 and SBT1/SBB1, and the sense amplifier precharge logic 608 and 612 can be independently controlled relative to one another. To achieve this independent control, separate precharge devices are employed for precharging the common bitlines BLCOM/BLBCOM and the sense amplifier sensing nodes SBT0/SBB0 and SBT1/SBB1, controlled by their control signals BLPC, SAPC0 and SAPC1, respectively.

The second sense amplifier 604 includes second precharge logic 612 which is coupled with nodes SBT1 and SBB1. The precharge logic 612 is operative to selectively precharge nodes SBT1 and SBB1 to a prescribed voltage level as a function of a sense amplifier precharge control signal, SAPC1, supplied thereto during a precharge mode of operation of the sense amplifier 604. Second sense amplifier 604 further includes an output stage which, in this embodiment, comprises a PFET M16 and an NFET M17 connected in series between VDD and ground. Specifically, a first source/drain of M16 is adapted for connection with VDD, a second source/drain of M16 is connected with a first source/drain of M17 at node OUT1 which forms an output of the second sense amplifier 604, a second source/drain of M17 is adapted for connection with ground, a gate of M16 is connected with node SBT1, and a gate of M17 is connected with node SBB1 through an inverter 614. Alternative output stage arrangements are similarly contemplated.

The outputs OUT0 and OUT1 of the sense amplifiers 602 and 604, respectively, are coupled together at a common node, OUT, and fed to an input of the latch circuit 606. In this illustrative embodiment, the latch circuit comprises a pair of cross-coupled inverters, although alternative latch circuit arrangements are similarly contemplated by embodiments of the invention. Specifically, an output of a first inverter 618, which is a clocked inverter, and an input of a second inverter 616, which may be a standard inverter, are connected with the combined output node OUT, and an input of inverter 618 is connected with an output of inverter 616 to form an output of the memory sensing architecture 600 for generating an output signal, DOUT, of the memory sensing architecture 600.

The inverter 618 is adapted to receive clock signals QCLK and QCLKB, which are complements of one another and function as latch control signals. Latch control signals QCLK and QCLKB are generated in a manner that places the inverter 618 in a high-impedance state during read access internally to update a status on DOUT as per sensed data; otherwise, inverter 618 provides positive feedback to inverter 616 to latch sensed data until it is written in a subsequent cycle.

In the memory sensing architecture 600, the first sense amplifier 602 and the second sense amplifier 604 are connected to a common pair of true and complementary bitlines to be sensed. The true and complementary bitlines have been combined separately from one another as nodes BLCOM and BLBCOM, respectively, using a multiplexing circuit 619. In the exemplary embodiment shown, the multiplexing circuit 619 utilizes a MUX4 implementation in which four pairs of bitlines, namely, BL0/BLB0, BL1/BLB1, BL2/BLB2, and BL3/BLB3, are separately combined into the common bitline node pair BLCOM/BLBCOM. It is to be appreciated, however, that the invention is not limited to any specific number of bitlines combined. The multiplexing circuit 619, which in this embodiment also includes bitline precharge functionality, comprises a plurality of PFETs M0M, M1M, M2M, M3M, M4M, M5M, M6M and M7M, each PFET being operative to selectively couple a given one of the common bitlines to a corresponding bitline, as will be described in further detail below.

More particularly, with reference to FIG. 6, a first source/drain of M0M is adapted for connection with bitline BL0, a second source/drain of M0M is connected with true common bitline BLCOM, and a gate of M0M is adapted to receive control signal Sel0. A first source/drain of M1M is adapted for connection with bitline BL1, a second source/drain of M1M is connected with BLCOM, and a gate of M1M is adapted to receive control signal Sel1. A first source/drain of M2M is adapted for connection with bitline BL2, a second source/drain of M2M is connected with BLCOM, and a gate of M2M is adapted to receive control signal Sel2. A first source/drain of M3M is adapted for connection with bitline BL3, a second source/drain of M3M is connected with BLCOM, and a gate of M3M is adapted to receive control signal Sel3. Likewise, a first source/drain of M4M is adapted for connection with bitline BLB0, a second source/drain of M4M is connected with complementary common bitline BLBCOM, and a gate of M4M is adapted to receive the control signal Sel0. A first source/drain of M5M is adapted for connection with bitline BLB1, a second source/drain of M5M is connected with BLBCOM, and a gate of M5M is adapted to receive the control signal Sel1. A first source/drain of M6M is adapted for connection with bitline BLB2, a second source/drain of M6M is connected with BLBCOM, and a gate of M6M is adapted to receive the control signal Sel2. A first source/drain of M7M is adapted for connection with bitline BLB3, a second source/drain of M7M is connected with BLBCOM, and a gate of M7M is adapted to receive the control signal Sel3.

In terms of operation of the multiplexing circuit 619, only one of the bitline selection control signals SEL0 through SEL3 is active at a given time so as to avoid shorting two bitline together. For example, asserting the SEL0 signal (e.g., low level) with SEL1, SEL2 and SEL3 control signals de-asserted (e.g., high level) turns on PFETs M0M and M4M and turns off the remaining PFETs, thereby connecting complementary bitline pair BL0 and BLB0 to the common bitlines BLCOM and BLBCOM, respectively.

Precharge logic 620 associated with the bitlines is coupled with the common bitline nodes BLCOM and BLBCOM. The precharge logic 620 is operative to selectively precharge nodes BLCOM and BLBCOM to a prescribed voltage level as a function of a bitline precharge control signal, BLPC, supplied thereto during a precharge mode of operation of a memory circuit in which the sense amplifier are employed (e.g., prior to a read access mode of operation). Thus, the bitline precharge logic 620 is operative in a manner consistent with the bitline precharge logic 212 shown in FIG. 2 and described above. The precharge logic 620 may be included in the multiplexing circuit 619 or, according to other embodiments, may reside externally to the multiplexing circuit.

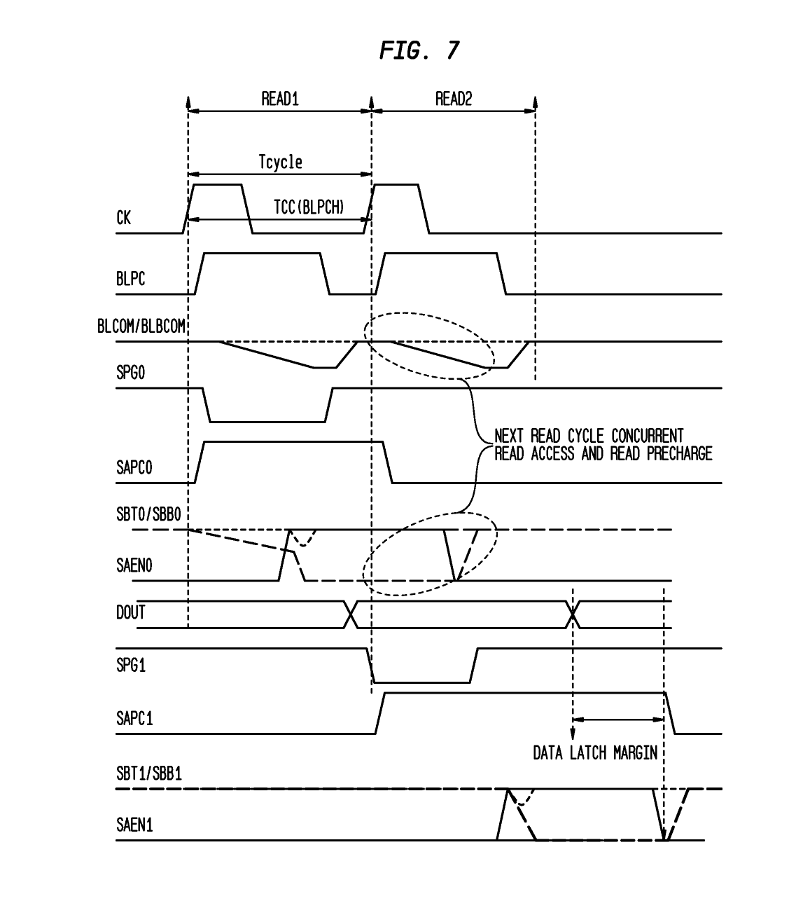

FIG. 7 depicts illustrative timing waveforms for certain signals associated with the exemplary memory sensing architecture 600 shown in FIG. 6, according to an embodiment of the invention. At least a portion of two consecutive memory read cycles are shown in FIG. 7 to illustrate a benefit of utilizing two sense amplifiers per sensed bit, according to an embodiment of the invention. With reference to FIGS. 6 and 7, during an initial portion of a first read cycle (READ1), the common bitline precharge control signal BLPC is set high to turn off the bitline precharge logic 620 and the sense amplifier precharge control signal SAPC0 is set high to turn off the first sense amplifier precharge logic 608. During the first read cycle, one of the pairs of read pass gates of the input multiplexer 619 (e.g., M0M/M4M, M1M/M5M, M2M/M6M, or M3M/M7M) is activated (e.g., one of control signals Sel0 through Sel3 is set low) and the first sense amplifier control signal SPG0 is set low to turn on PFET pass gates M0 and M6 and thereby connect the first sense amplifier 602 to the pair of common bitlines BLCOM and BLBCOM, respectively. A selected memory cell will then discharge a coupled bitline or its complement, depending on the data stored therein, and a corresponding voltage indicative of the logic state stored in the selected memory cell will be developed across the internal sensing nodes SBT0 and SBB0 of the first sense amplifier 602.

Once the differential voltage between the internal sensing nodes SBT0 and SBB0 of the first sense amplifier 602 reaches or exceeds a prescribed threshold voltage, which may be a sense amplifier offset voltage, a memory self-time mechanism (which may be generated, for example, by timing circuitry or an alternative controller (e.g., finite state machine) in the memory circuit) is operative to assert the first sense amplifier enable signal SAEN0 (by setting SAEN0 high) and, substantially concurrently therewith, to de-assert the sense amplifier control signal SPG0 (by setting SPG0 high). Once the sense amplifier control signal SPG0 is de-asserted, the pass gates M0 and M6 turn off, thereby isolating the internal sensing node SBT0 and SBB0 in the first sense amplifier 602 from the common bitlines BLCOM and BLBCOM. With the bitlines BLCOM and BLBCOM isolated from the sensing nodes SBT0 and SBB0, the bitline precharge logic 620 can be activated by asserting the bitline precharge control signal BLPC (by setting BLPC high) to turn on the bitline precharge logic 620 to be ready for the start of the next read cycle. The sense amplifier enable signal SAEN0 remains asserted at least until the output data DOUT generated by the sense amplifier 602 is properly latched by latch circuit 606. To accomplish this, a pulse width of the sense amplifier enable signal SAEN0 is controlled, such as, for example, using a delay chain or alternative timing circuitry, such that the SAEN0 pulse width is sufficient to ensure a positive latch margin, Tmarg_latch, for all bit depths and across all anticipated integrated circuit (IC) fabrication process, supply voltage and temperature (PVT) conditions.

A second read cycle (READ2) is initiated once the common bitline nodes BLCOM/BLBCOM have been precharged to a prescribed voltage level. Using the sensing architecture 600, the second read cycle is beneficially started without waiting for the sensing and precharge operation of the selected sense amplifier 602 to complete. In the second read cycle, control signals place the second sense amplifier 604 in an active memory path, enabling read access of the second sense amplifier 604 and a precharge operation of the first sense amplifier 602 to occur in parallel (i.e., concurrently), thereby reducing cycle time significantly. In the case of two consecutive read operations, the internal sensing nodes SBT0 and SBB0 in the first sense amplifier 602 are precharged before the next accessed sense amplifier enable signal assertion to avoid any contention between sense amplifier output nodes OUT0 and OUT1.

Embodiments of the invention provide a mechanism which utilizes at least two sense amplifiers and a controller operative to control connection of the two sense amplifiers in the memory active path in a manner which makes memory cycle time essentially independent of sense reaction/data latch and sense precharging time to thereby beneficially decrease overall memory cycle time. Embodiments of the invention further provide the freedom to extend sense amplifier enable signal assertion (SAEN0, SAEN1) to satisfy a prescribed data latch race condition margin (Tmarg_latch) without penalizing cycle time, which is beneficial in memory compiler design where multiple word width and depth can have different requirements for sense enable assertion signal width.

FIG. 8 conceptually illustrates simulation results showing a percentage improvement in cycle time for an exemplary memory sensing architecture in accordance with an embodiment of the invention compared with a conventional memory sensing design. With reference to FIG. 8, simulation data is shown for three word lengths, namely, 32, 80 and 128 bits, for bit depths varying between 8 and 256 bits (horizontal axis) for slow integrated circuit fabrication process, high supply voltage (e.g., 0.765 volt) and low temperature (e.g., zero degrees Celsius) conditions. It is to be appreciated, however, that the invention is not limited to the specific word lengths and/or bit depths shown. Rather, the three design ranges have been introduced based upon a number of bits which provide a favorable sense pulse width throughout the compiler range. Depending upon the absolute number of the cycle time, the percentage of improvement is higher for shorter word lengths.

From the bitline discharge node to the sense amplifier internal node (SBT/SBB) in the memory sensing architecture 600 shown in FIG. 6, there are two sets of series PFETs; one set which includes M[0-7]M in the bitline multiplexing circuit 619 and one set which includes series pass gates M0/M6 or M9/M15 in the sense amplifiers 602, 604. If the design is implemented using high voltage threshold (HVT) or ultra-high voltage threshold (UHVT) transistors, their resistance can be significant, and thus a resistive drop across each pass transistor can be high.

In accordance with alternative embodiments of the invention, in the memory sensing architecture 600 shown in FIG. 6, two multiplexing circuits 619 can be independently used (and controlled with comparable sets of control signals to avoid use of pass gates M0/M6 or M9/M15) coupled with the sense amplifiers (e.g., 602, 604) to avoid minute differential losses caused by increased capacitance on the common bitlines BLCOM and BLBCOM and by increased resistance resulting from the introduction of series pass gates in the sense amplifiers (e.g., M0, M6, M9, M15). In this embodiment, a first bitline multiplexing circuit (e.g., 619) is coupled directly with nodes SBT0, SBB0 of the first sense amplifier 602, and a second bitline multiplexing circuit (not explicitly shown in FIG. 6) is coupled directly with nodes SBT1, SBB1 of the second sense amplifier circuit 604. Implementation as per this alternative embodiment will remove one series pass gate in a path from the bitline discharge node to the sense amplifier internal node (SBT0, SBB0).

Although the illustrative memory sensing architecture 600 depicted in FIG. 6 is described in conjunction with a bitline multiplexing arrangement (e.g., MUX4), it is to be understood that, in accordance with other embodiments, each pair of sense amplifiers can be connected directly with a corresponding differential bitline pair, thereby eliminating the need for bitline multiplexing altogether. This is particularly true where higher performance is desired at the expense of increased integrated circuit area. In a compiler design where multiple column multiplexer options are provided, embodiments of the invention can be applied to make use of a higher degree of column multiplexing without any significant area penalty.

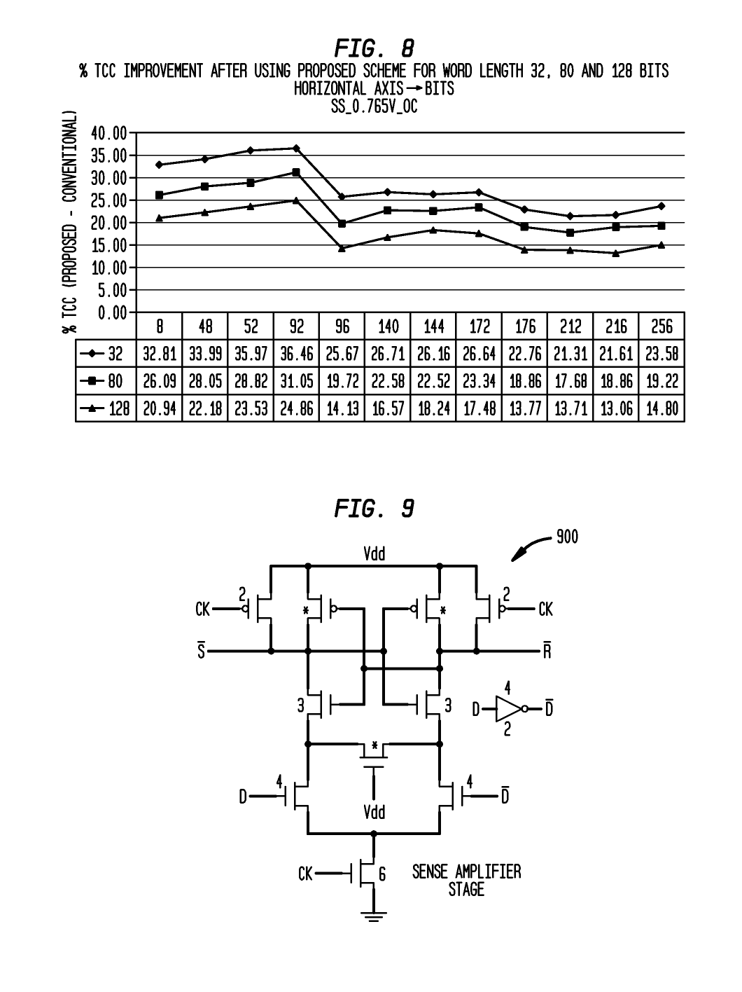

Although embodiments of the invention have been described herein in conjunction with a specific sense amplifier design, it is to be appreciated that the embodiments of the invention are limited to the specific sense amplifier design shown. For example, FIG. 9 is a schematic diagram depicting at least a portion of an exemplary sense amplifier circuit 900 suitable for use with the illustrative sensing architecture 600 shown in FIG. 6. More particularly, in the sensing architecture 600, each of sense amplifiers 602 and 604, in accordance with an alternative embodiment, are replaced with the sense amplifier circuit 900. Here, the signals BLCOM and BLBCOM are connected to the D and D inputs, respectively, of the sense amplifier circuit 900.

At least a portion of the techniques of embodiments of the invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Integrated circuits so manufactured are considered part of this invention.

An integrated circuit in accordance with embodiments of the invention can be employed in essentially any application and/or electronic system in which memory may be employed. Suitable systems for implementing techniques according to embodiments of the invention may include, but are not limited to, data processing systems, personal computers, data storage systems, communications networks, etc. Systems incorporating such integrated circuits are considered part of embodiments of the invention. Given the teachings of embodiments of the invention provided herein, one of ordinary skill in the art will be able to contemplate other implementations and applications of the techniques of embodiments of the invention.

The illustrations of embodiments of the invention described herein are intended to provide a general understanding of the architecture of various embodiments of the invention, and they are not intended to serve as a complete description of all the elements and features of apparatus and systems that might make use of the architectures and circuits according to embodiments of the invention described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not drawn to scale. Accordingly, the specification and drawings are to be regarded in an illustrative rather than a restrictive sense.

Embodiments of the inventive subject matter are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The abstract is provided to comply with 37 C.F.R. §1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. A sensing circuit for use in a memory including a plurality of memory cells and at least one bitline coupled with the memory cells, the sensing circuit comprising:
a first sense amplifier adapted to read a logical state of a selected one of the memory cells that is coupled to the first sense amplifier via a first corresponding bitline;
a second sense amplifier adapted to read a logical state of a selected one of the memory cells that is coupled to the second sense amplifier via a second corresponding bitline; and
a controller coupled with the first and second sense amplifiers and operative to selectively connect one of the first and second sense amplifiers in an active path of the memory in a manner which enables one of the sense amplifiers to be operative in a precharge mode and another of the sense amplifiers to be concurrently operative in a sensing mode during a given memory cycle.

2. The sensing circuit of claim 1, wherein the memory comprises a plurality of complementary bitlines, and wherein the sensing circuit further comprises a multiplexer including at least first and second inputs coupled with first and second bitlines, respectively, and an output independently coupled with a sensing node in each of the first and second sense amplifiers as a function of corresponding first and second control signals.

3. The sensing circuit of claim 1, wherein each of the first and second sense amplifiers comprises switching circuitry coupling the sense amplifier to a corresponding bitline, the switching circuitry being configured to selectively isolate at least one sensing node in the sense amplifier from the corresponding bitline as a function of a control signal.

4. The sensing circuit of claim 1, wherein each of the first and second sense amplifiers comprises switching circuitry coupling the sense amplifier to a corresponding pair of complementary bitlines, the switching circuitry in the first sense amplifier being configured to selectively isolate differential sensing nodes in the first sense amplifier from the corresponding pair of complementary bitlines as a function of a first control signal, and the switching circuitry in the second sense amplifier being configured to selectively isolate differential sensing nodes in the second sense amplifier from the corresponding pair of complementary bitlines as a function of a second control signal.

5. The sensing circuit of claim 4, wherein the first and second control signals are asserted independently of one another.

6. The sensing circuit of claim 1, wherein each of the first and second sense amplifiers further comprises a latch circuit operative to at least temporarily store a logical state of an output of the sense amplifier as a function of a clock signal supplied to the latch circuit.

7. The sensing circuit of claim 6, wherein the latch circuit in each of the first and second sense amplifiers comprises first and second inverters, at least the first inverter being a clocked inverter adapted to receive the clock signal, an output of the first inverter and an input of the second inverter being connected with an output of the sense amplifier, and an input of first inverter being connected with an output of the second inverter and generating an output signal of the sensing circuit that is indicative of the logical state of the selected one of the memory cells.

8. The sensing circuit of claim 6, wherein a given one of the first and second sense amplifiers remains asserted during a given memory cycle at least until an output data signal generated by the given sense amplifier is latched by the latch circuit.

9. The sensing circuit of claim 1, further comprising a latch circuit coupled with the first and second sense amplifiers, the latch circuit being operative to selectively store a logical state of an output of a given one of the first and second sense amplifiers as a function of a clock signal supplied to the latch circuit.

10. The sensing circuit of claim 9, wherein each of the first and second sense amplifiers comprises multiplexing circuitry operative to selectively couple an output of the sense amplifier with the latch circuit as a function of a corresponding control signal.

11. The sensing circuit of claim 9, wherein the latch circuit comprises first and second inverters, at least the first inverter being a clocked inverter adapted to receive the clock signal, an output of the first inverter and an input of the second inverter being connected with respective outputs of the first and second sense amplifiers, and an input of first inverter being connected with an output of the second inverter and generating an output signal of the sensing circuit that is indicative of the logical state of the selected one of the memory cells.

12. The sensing circuit of claim 9, wherein assertion of one of the first and second sense amplifiers is delayed until an output data signal generated by another of the first and sense amplifiers is latched by the latch circuit to thereby avoid contention between respective output nodes of the first and second sense amplifiers.

13. The sensing circuit of claim 1, wherein each of at least one of the first and second sense amplifiers comprises:
a pair of cross-coupled inverters selectively connected with a pair of complementary bitlines in the memory via corresponding access devices as a function of a first control signal, the pair of inverters being active in the sensing mode to determine a logical state of the selected memory cell; and
a precharge circuit selectively coupled with at least one sensing node in the sense amplifier as a function of a second control signal, the precharge circuit being active during the precharge mode to set the at least one sensing node to a prescribed voltage level.

14. The sensing circuit of claim 1, wherein each of at least one of the first and second sense amplifiers comprises:
first and second inverters, an input of the first inverter being connected with an output of the second inverter at a first sensing node, and an output of the first inverter being connected with an input of the second inverter at a second sensing node;
first and second switching elements, the first switching element being operative to selectively connect the first sensing node with a first bitline of a corresponding pair of complementary bitlines in the memory as a function of a first control signal, the second switching element being operative to selectively connect the second sensing node with a second bitline of the corresponding pair of complementary bitlines as a function of the first control signal; and
a precharge circuit selectively coupled with the first and second sensing nodes in the sense amplifier as a function of a second control signal;
wherein the first and second inverters are connected with the corresponding pair of complementary bitlines and operative to sense a logical state of a selected memory cell in the memory during the sensing mode, and the precharge circuit is active during a precharge mode to set the first and second sensing nodes to a prescribed voltage level.

15. The sensing circuit of claim 1, wherein at least a portion of the sensing circuit is fabricated in at least one integrated circuit.

16. A method for reducing memory cycle time in a memory circuit including a plurality of memory cells, at least one bitline coupled with the memory cells, and at least two sense amplifiers, the method comprising steps of:
during a first memory cycle, enabling a first one of the sense amplifiers for reading a logical state of a selected one of the memory cells coupled to the first one of the sense amplifiers via a first corresponding bitline and enabling a second one of the sense amplifiers for precharging at least one sensing node in the second one of the sense amplifiers; and
during a second memory cycle, enabling the second one of the sense amplifiers for reading a logical state of a selected one of the memory cells coupled to the second one of the sense amplifiers via a second corresponding bitline and enabling the first one of the sense amplifiers for precharging at least one sensing node in the first one of the sense amplifiers.

17. The method of claim 16, wherein steps of enabling one of the sense amplifiers for reading a logical state of a selected one of the memory cells and enabling another of the sense amplifiers for precharging at least one sensing node are performed substantially concurrently.

18. The method of claim 16, wherein enabling a given one of the sense amplifiers for reading a logical state of a selected one of the memory cells comprises controlling a connection of the at least two sense amplifiers in a memory active path in a manner which makes memory cycle time independent of sensing time and precharging time in the memory circuit.

19. The method of claim 16, further comprising multiplexing a plurality of bitlines in the memory circuit such that a selected one of the bitlines is connected with a given one of the sense amplifiers during a memory cycle.

20. The method of claim 16, further comprising latching an output data signal generated by a given one of the sense amplifiers and disconnecting the given one of the sense amplifiers from a memory active path in the memory circuit once a prescribed latch margin has been met.

21. A memory circuit, comprising:
a plurality of bitlines;
a plurality of memory cells, each of the memory cells being adapted for connection with a corresponding one of the bitlines for selectively accessing the memory cell; and
at least one sensing circuit, the at least one sensing circuit comprising:
a first sense amplifier adapted to read a logical state of a selected one of the memory cells that is coupled to the first sense amplifier via a first corresponding bitline;
a second sense amplifier adapted to read a logical state of a selected one of the memory cells that is coupled to the second sense amplifier via a second corresponding bitline; and
a controller coupled with the first and second sense amplifiers and operative to selectively connect one of the first and second sense amplifiers in an active path of the memory in a manner which enables one of the sense amplifiers to be operative in a precharge mode and another of the sense amplifiers to be concurrently operative in a sensing mode during a given memory cycle.

22. The memory circuit of claim 21, wherein the memory circuit is fabricated as at least a portion of an embedded memory.

23. The memory circuit of claim 21, wherein the memory circuit is fabricated as at least a portion of a standalone memory.
